(19) United States
(12) Patent Application Publication
(10) Pub. No.: US 2026/0075840 A1
(43) Pub. Date: Mar. 12, 2026

(54) SEMICONDUCTOR DEVICE HAVING SELECTION ELEMENTS

(71) Applicant: SK hynix Inc., Gyeonggi-do (KR)

(72) Inventor: Jeong Hwan SONG, Gyeonggi-do (KR)

(21) Appl. No.: 19/207,375

(22) Filed: May 14, 2025

(30) Foreign Application Priority Data
Sep. 10, 2024 (KR) 10-2024-0123272

(51) Int. Cl. H10B 63/00

(52) U.S. Cl. CPC H10B 63/24; H10B 63/80

(57) ABSTRACT

A semiconductor device includes a cell area including a first sub-cell area and a second sub-cell are; a first peripheral circuit area adjacent to one side of the cell area in a first direction; and a second peripheral circuit area adjacent to another side of the cell area in a second direction perpendicular to the first direction. The first sub-cell area includes a first memory cell disposed closer to the first and second peripheral circuit areas than the second memory cell. The second sub-cell area includes a second memory cell disposed farther from the first and second peripheral circuit areas. The first and second memory cells include first and second selection element layers, respectively, each selection element layer including a dielectric material containing a dopant. A dopant concentration of the first selection element layer is lower than a dopant concentration of the second selection element layer.

### CROSS-REFERENCE TO RELATED APPLICATIONS

The present application claims priority under 35 U.S.C 119(a) to Korean Patent Application No. 10-2024-0123272, filed on Sep. 10, 2024, which is incorporated herein by reference in its entirety.

### BACKGROUND

### 1. Field

Embodiments of the present disclosure relate to a semiconductor device, and more particularly, to a semiconductor device including memory cells having selection element layers, and a method for fabricating the semiconductor device.

### 2. Description of the Related Art

Recent demands for miniaturization, low power consumption, high performance, and diversification of electronic devices require semiconductor devices capable of storing data in various electronic devices, such as computers, portable communication devices and the like, and researchers and industry are studying to develop such semiconductor devices. Such semiconductor devices include semiconductor devices capable of storing data by using the characteristics of switching between different resistance states according to the applied voltage or current, such as a Resistive Random Access Memory (RRAM), a Phase-change Random Access Memory (PRAM), a Ferroelectric Random Access Memory (FRAM), a Magnetic Random Access Memory (MRAM), an E-fuse and the like.

### SUMMARY

Embodiments of the present disclosure are directed to a semiconductor device capable of uniformizing a threshold voltage of memory cells regardless of their positions.

Further, embodiments of the present disclosure are directed to a semiconductor device capable of uniformizing the characteristics of memory cells.

In accordance with an embodiment of the present disclosure, a semiconductor device includes a cell area including a first sub-cell area and a second sub-cell are; a first peripheral circuit area adjacent to a first side of the cell area in a first direction; and a second peripheral circuit area adjacent to a second side of the cell area in a second direction perpendicular to the first direction. The first sub-cell area includes a first memory cell disposed closer to the first and second peripheral circuit areas than the second memory cell, and the second sub-cell area includes a second memory cell disposed farther from the first and second peripheral circuit areas. The first memory cell includes a first selection element layer and the second memory cell includes a second selection element layer, each of the first and second selection element layers including a dielectric material containing a dopant. A dopant concentration of the first selection element layer is lower than a dopant concentration of the second selection element layer.

In accordance with another embodiment of the present disclosure, a semiconductor device includes a cell area including a first memory cell and a second memory cell; and a first peripheral circuit area disposed adjacent to the cell area in a first direction. The first memory cell is disposed closer to the first peripheral circuit area than the second memory cell, and the first memory cell includes a first selection element layer having a first threshold voltage, and the second memory cell includes a second selection element layer having a second threshold voltage lower than the first threshold voltage.

### BRIEF DESCRIPTION OF THE DRAWINGS

FIG. 1A is a perspective view schematically illustrating a cell array of a semiconductor device in accordance with an embodiment of the present disclosure.

FIG. 1B is a top view illustrating a block arrangement of a semiconductor device in accordance with an embodiment of the present disclosure.

FIGS. 2A to 2D illustrate a cell area of a semiconductor device including a plurality of sub-cell areas in accordance with embodiments of the present disclosure.

FIG. 3 is a cross-sectional view illustrating a semiconductor device in accordance with an embodiment of the present disclosure.

FIGS. 4A to 4H are cross-sectional views illustrating a method of forming memory cell structures of a semiconductor device in accordance with an embodiment of the present disclosure.

FIGS. 5A to 5D are cross-sectional views illustrating a method of forming memory cell structures of a semiconductor device in accordance with an embodiment of the present disclosure.

### DETAILED DESCRIPTION

Embodiments of the present disclosure will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments.

Hereinafter, the various embodiments of the present disclosure will be described in detail with reference to the attached drawings.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present disclosure.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element. When a first element is referred to as being “on” a second element, it refers to a case where the first element is formed directly or indirectly on the second element or the substrate.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

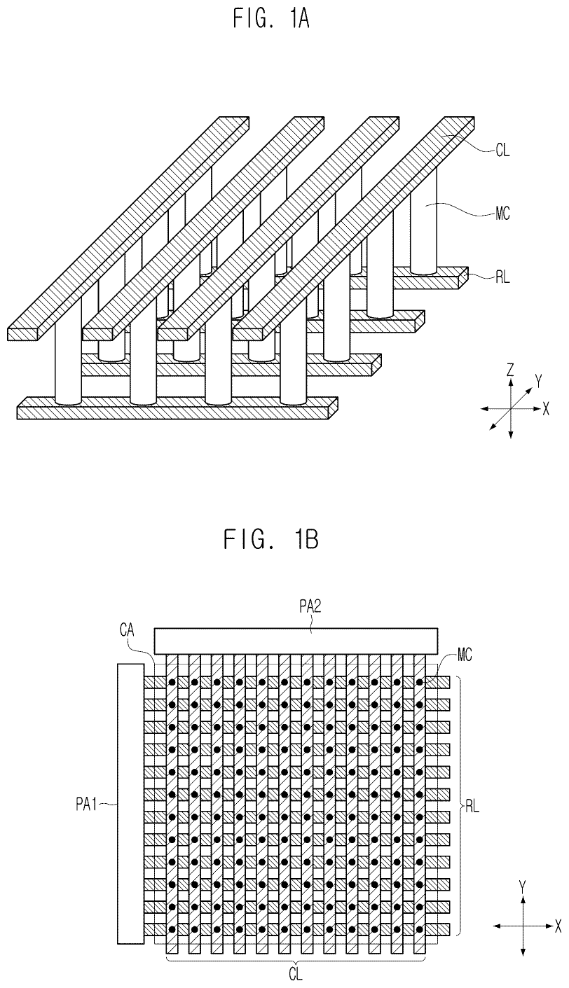

FIG. 1A is a perspective view schematically illustrating a cell array of a semiconductor device in accordance with an embodiment of the present disclosure. FIG. 1B is a top view illustrating a block arrangement of the semiconductor device. Referring to FIGS. 1A and 1B, the cell array of the semiconductor device may include a plurality of row interconnection lines RL extending in parallel to a first direction X, a plurality of column interconnection lines CL extending in parallel to a second direction Y which intersects with the first direction X, and memory cells MC disposed at intersections between the row interconnection lines RL and the column interconnection lines CL. The memory cells MC may be disposed to have a pillar shape extending in a third direction Z between the row interconnection lines RL and the column interconnection lines CL. The first direction X, the second direction Y, and the third direction Z may be perpendicular to each other.

The semiconductor device may include a cell area CA, a first peripheral circuit area PA1, and a second peripheral circuit area PA2. The first peripheral circuit area PA1 may be disposed adjacent to a first side of the cell area CA in the first direction X. For example, the first peripheral circuit area PA1 may include a row interconnection line drive circuit. The second peripheral circuit area PA2 may be disposed adjacent to a second side of the cell area CA in the second direction Y. For example, the second peripheral circuit area PA2 may include a column interconnection line drive circuit. Accordingly, the row interconnection lines RL may extend from the first peripheral circuit area PA1 and pass through the cell area CA in the first direction X. The column interconnection lines CL may extend from the second peripheral circuit area PA2 and pass through the cell area CA in the second direction Y. The row interconnection lines RL and the column interconnection lines CL may intersect with each other in the cell area CA. In an embodiment the row interconnection lines RL may correspond to word lines, and the column interconnection lines CL may correspond to bit lines. In another embodiment, the row interconnection lines RL may correspond to the bit lines, and the column interconnection lines CL may correspond to the word lines. The row interconnection lines RL may have substantially uniform and same resistance in the cell area CA. For example, the row interconnection lines RL may have the same structure, the same material, the same width, and the same thickness in the cell area CA. The column interconnection lines CL may have substantially uniform and same resistance in the cell area CA. For example, the column interconnection lines CL may have the same structure, the same material, the same width, and the same thickness in the cell area CA.

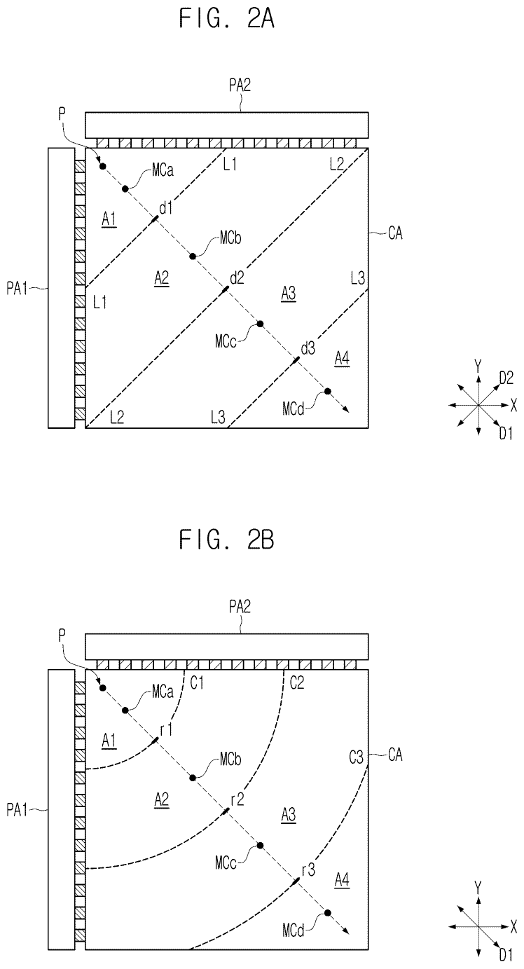

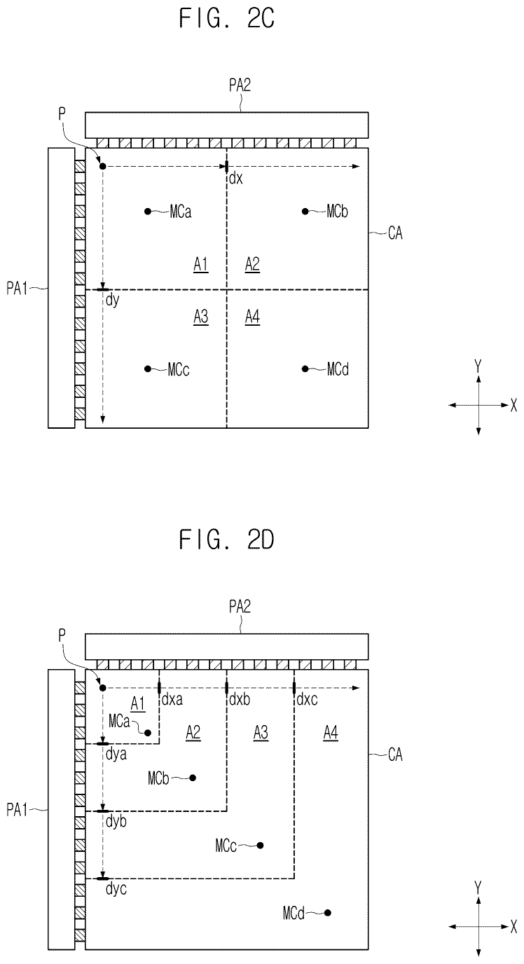

FIGS. 2A to 2D illustrate the cell area CA of the semiconductor device including sub-cell areas A1 to A4. For example, the cell area CA may be separated into sub-cell areas A1 to A4. Referring to FIGS. 2A to 2C, the cell area CA may include a sub-cell areas A1, a second sub-cell area A2, a third sub-cell area A3, and a sub-cell area A4. The sub-cell areas A1 to A4 may be separated according to spacing distances d1 to d3, r1 to r3, and dx to dy from a reference point P. The reference point P may be a memory cell disposed closest to the first peripheral circuit area PA1 and the second peripheral circuit area PA2 in the cell area CA. For example, the reference point P may be disposed adjacent to a first corner (e.g., the upper left corner) of the cell area CA. The first corner may be closest to the first peripheral circuit area PA1 and the second peripheral circuit area PA2.

Referring to FIG. 2A, the cell area CA may include a plurality of sub-cell areas A1 to A4 that are separated by a plurality of boundary lines L1 to L3. The boundary lines L1 to L3 may extend in a second diagonal direction d2 to have a first spacing distance d1, a second spacing distance d2, and a third spacing distance d3 from the reference point P in a first diagonal direction D1. Accordingly, the first sub-cell area A1 may include first memory cells MCa that are disposed within the first boundary line L1 from the reference point P, and the second sub-cell area A2 may include second memory cells MCb that are disposed between the first boundary line L1 and the second boundary line L2 from the reference point P, and the third sub-cell area A3 may include third memory cells MCc that are disposed between the second boundary line L2 and the third boundary line L3 from the reference point P, and the fourth sub-cell area A4 may include fourth memory cells MCd that are disposed outside of the third boundary line L3 from the reference point P. In an embodiment of the present disclosure, the boundary lines L1 to L3 may have a serpentine shape so as not to cross the memory cells MC from a microscopic perspective.

Referring to FIG. 2B, the cell area CA may include a plurality of sub-cell areas A1 to A4 separated by a plurality of concentric circle-shaped boundary curves C1 to C3. The boundary curves C1 to C3 may have a concentric circular arc shape centering around the reference point P. Accordingly, each of the first to fourth sub-cell areas A1 to A4 may have a sector shape or a track sector shape. The first sub-cell area A1 may include first memory cells MCa that are disposed within the first boundary curve C1 having a radius of a first spacing distance r1 in the first diagonal direction D1 from the reference point P. The second sub-area A2 may include second memory cells MCb that are disposed between the first boundary curve C1 having a radius of the first spacing distance r1 from the reference point P and the second boundary curve C2 having a radius of a second spacing distance r2. The third sub-cell area A3 may include third memory cells MCc that are disposed between the second boundary curve C2 having a radius of the second spacing distance r2 from the reference point P and the third boundary curve C3 having a radius of a third spacing distance r3 from the reference point P. The fourth sub-cell area A4 may include fourth memory cells MCd that are disposed outside of the third boundary curve C3 having a radius of the third spacing distance r3 from the reference point P. Each of the boundary curves C1 to C3 may also have a serpentine shape in order not to cross the first to fourth memory cells MCa to MCd from the microscopic perspective.

Referring to FIG. 2C, the cell area CA may include a plurality of sub-cell areas A1 to A4 separated based on a predetermined distance dx and dy in the first direction X and the second direction Y from the reference point P. The cell areas A1 to A4 may include a first sub-cell area A1 including first memory cells MCa that are disposed within a first distance dx in the first direction X and a second distance dy in the second direction Y from the reference point P, a second sub-cell area A2 including second memory cells MCb that are disposed behind the first distance dx in the first direction X and disposed within the second distance dy in the second direction Y from the reference point P, a third sub-cell area A3 including third memory cells MCc that are disposed within the first distance dx in the first direction X and disposed behind the second distance dy in the second direction Y from the reference point P, and a fourth sub-cell area A4 including fourth memory cells MCd that are disposed behind the first distance dx in the first direction X and disposed behind the second distance dy in the second direction Y from the reference point P.

Referring to FIG. 2D, the cell area CA may include a plurality of sub-cell areas A1 to A4 that are split based on a first distance dxa, a second distance dxb, and a third distance dxc in the first direction X from the reference point P, and based on a first distance dya, a second distance dyb, and a third distance dyc in the second direction Y. The cell areas A1 to A4 may include a first sub-cell area A1 including first memory cells MCa that are disposed within the first distance dxa in the first direction X and the first distance dya in the second direction Y from the reference point P, a second sub-cell area A2 including second memory cells MCb that are disposed behind the first distance dxa and within the second distance dxb in the first direction X from the reference point P, and disposed behind the first distance dya and within the second distance dyb in the second direction Y from the reference point P, a third sub-cell area A3 including third memory cells MCc that are disposed behind the second distance dxb and within the third distance dxc in the first direction X from the reference point P, and disposed behind the second distance dyb and within the third distance dyc in the second direction Y from the reference point P, and a fourth sub-cell area A4 including fourth memory cells MCd that are disposed behind the third distance dxc in the first direction X from the reference point P and disposed behind the third distance dyc in the second direction Y from the reference point P.

According to the embodiments of the present disclosure, the cell area CA may include at least two or more sub-cell areas A1 to A4. The cell area CA may be split into at least two or more sub-cell areas. According to the embodiments of the present disclosure, the cell area CA may be split into a plurality of sub-cell areas A1 to A4 from the sub-cell area A1 closest to the reference point P to the sub-cell area A4 farthest from the reference point P.

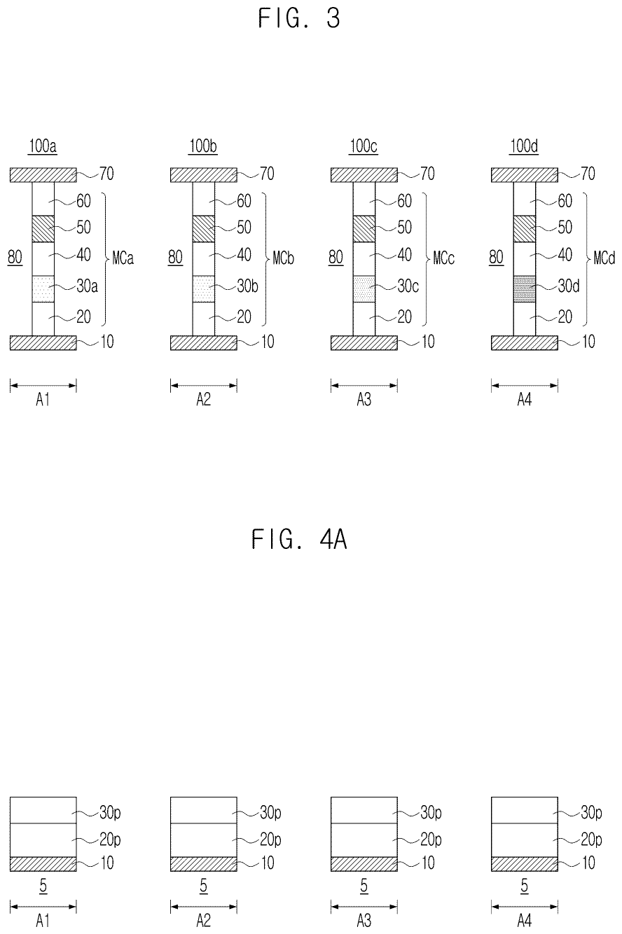

FIG. 3 is a cross-sectional view illustrating a semiconductor device in accordance with an embodiment of the present disclosure. Referring to FIG. 3, the semiconductor device may include first to fourth memory cell structures 100a to 100d. The first to fourth memory cell structures 100a to 100d may include lower interconnection lines 10, first to fourth memory cells MCa to MCd disposed over the lower interconnection lines 10, and upper interconnection lines 70 disposed over the first to fourth memory cells MCa to MCd, respectively. Each of the first to fourth memory cells 100a to 100d may have a pillar shape.

The lower interconnection lines 10 may correspond to the row interconnection lines RL of FIGS. 1A and 1B. The upper interconnection line 70 may correspond to the column interconnection lines CL of FIGS. 1A and 1B. Each of the lower interconnection lines 10 and the upper interconnection lines 70 may include at least one of a metal layer such as tungsten (W), a metal compound layer such as titanium nitride (TiN), a metal alloy layer, and a metal silicide layer.

Referring to FIGS. 2A to 2D, the first memory cell structure 100a may be disposed in the first sub-cell area A1, and the second memory cell structure 100b may be disposed in the second sub-cell area A2, and the third memory cell structure 100c may be disposed in the third sub-cell area A3, and the fourth memory cell structure 100d may be disposed in the fourth sub-cell area A4.

The first memory cell MCa may include a lower electrode 20, a first selection element layer 30a disposed over the lower electrode 20, an intermediate electrode 40 disposed over the first selection element layer 30a, a memory element layer 50 disposed over the intermediate electrode 40, and an upper electrode 60 disposed over the memory element layer 50. The second memory cell MCb may include a lower electrode 20, a second selection element layer 30b disposed over the lower electrode 20, an intermediate electrode 40 disposed over the second selection element layer 30b, a memory element layer 50 disposed over the intermediate electrode 40, and an upper electrode 60 disposed over the memory element layer 50. The third memory cell MCc may include a lower electrode 20, a third selection element layer 30c disposed over the lower electrode 20, an intermediate electrode 40 disposed over the third selection element layer 30c, a memory element layer 50 disposed over the intermediate electrode 40, and an upper electrode 60 disposed over the memory element layer 50. The fourth memory cell MCd may include a lower electrode 20, a fourth selection element layer 30d disposed over the lower electrode 20, an intermediate electrode 40 disposed over the fourth selection element layer 30d, a memory element layer 50 disposed over the intermediate electrode 40, and an upper electrode 60 disposed over the memory element layer 50.

Each of the lower electrode 20, the upper electrode 60, and the intermediate electrode 40 may include various conductive materials, for example, metals such as tungsten (W), aluminum (Al), copper (Cu), tantalum (Ta), titanium (Ti) and the like, metal nitrides such as titanium nitride (TiN), tantalum nitride (TaN) and the like, or a combination thereof. Further, each of the lower electrode 20, the intermediate electrode 40, and the upper electrode 60 may include a carbon electrode.

The memory element layer 50 may include a variable resistance element. For example, the memory element layer 50 may include at least one of a transition metal oxide layer, a metal oxide layer such as a perovskite-based material, a phase change material layer such as a chalcogenide-based material, a ferroelectric material layer, and a ferromagnetic material layer.

Each of the first to fourth selection element layers 30a to 30d may include a dielectric material containing a dopant. In an embodiment, each of the first to fourth selection element layers 30a to 30d may include an oxide containing a dopant, a nitride containing a dopant, or an oxynitride containing a dopant. The oxide containing a dopant may include at least one of a silicon oxide containing a dopant, a silicon nitride containing a dopant, a silicon oxynitride containing a dopant, a metal oxide containing a dopant, a metal nitride containing a dopant, and a metal oxynitride containing a dopant. The dopant may include at least one of aluminum, lanthanum, niobium, vanadium, tantalum, tungsten, chromium, molybdenum, boron, nitrogen, carbon, phosphorus, and arsenic.

The first selection element layer 30a may include dopants of a first dopant concentration. The second selection element layer 30b may include dopants of a second dopant concentration. The second dopant concentration may be higher than the first dopant concentration. The third selection element layer 30c may include dopants of a third dopant concentration. The third dopant concentration may be higher than the second dopant concentration. The fourth selection element layer 30d may include dopants of a fourth dopant concentration. The fourth dopant concentration may be higher than the third dopant concentration. In an embodiment, the first to fourth dopant concentrations may be appropriately selected in a range of approximately 1E15/cm³ to 1E16/cm³.

Each of the first peripheral circuit area PA1 and/or the second peripheral circuit area PA2 may have driving circuits. Accordingly, the first to fourth memory cells MCa to MCd in the cell area CA may be provided with voltages or currents of different levels from the first peripheral circuit area PA1 and/or the second peripheral circuit area PA2. A memory cell of the first to fourth memory cells MCa to MCd closest to the first peripheral circuit area PA1 and/or the second peripheral circuit area PA2, for example, the first memory cell MCa, may be provided with a relatively high voltage or high current compared to the other memory cells MCb to MCd. A memory cell of the first to fourth memory cells MCa to MCd farthest from the first peripheral circuit area PA1 and/or the second peripheral circuit area PA2, for example, the fourth memory cell MCd, may be provided with a relatively low voltage or low current compared to the other memory cells MCa to MCc.

Therefore, a memory cell disposed closer to the first peripheral circuit area PA1 and/or the second peripheral circuit area PA2 may be easily turned on compared to a memory cell farther from the first peripheral circuit area PA1 and/or the second peripheral circuit area PA2. Practically, the memory cell disposed closer to the first peripheral circuit area PA1 and/or the second peripheral circuit area PA2 may have a relatively low threshold voltage (Vth), compared to a memory cell farther from the first peripheral circuit area PA1 and/or the second peripheral circuit area PA2. To be specific, a first selection element layer 30a of a memory cell that is closest to the first peripheral circuit area PA1 and/or the second peripheral circuit area PA2, for example, a first memory cell MCa, may have a relatively high threshold voltage, and a fourth selection element layer 30d of a memory cell that is farthest from the first peripheral circuit area PA1 and/or the second peripheral circuit area PA2, for example, a fourth memory cell MCd, may have a relatively low threshold voltage. Accordingly, the operation of all memory cells MCa to MCd may not be uniform according to the difference in the threshold voltage.

According to an embodiment of the present disclosure, threshold voltages of the selection elements 30a to 30d may be adjusted according to the dopant concentrations of the selection element layers 30a to 30d included in the memory cells MCa to MCd, respectively. The threshold voltage, which varies according to the distance difference between the peripheral circuit area and the memory cells MCa to MCd, may be substantially uniformized according to the difference in the dopant concentrations of the selection element layers 30a to 30d. Accordingly, all memory cells MCa to MCd may be substantially commonly turned on and/or turned off to operate stably.

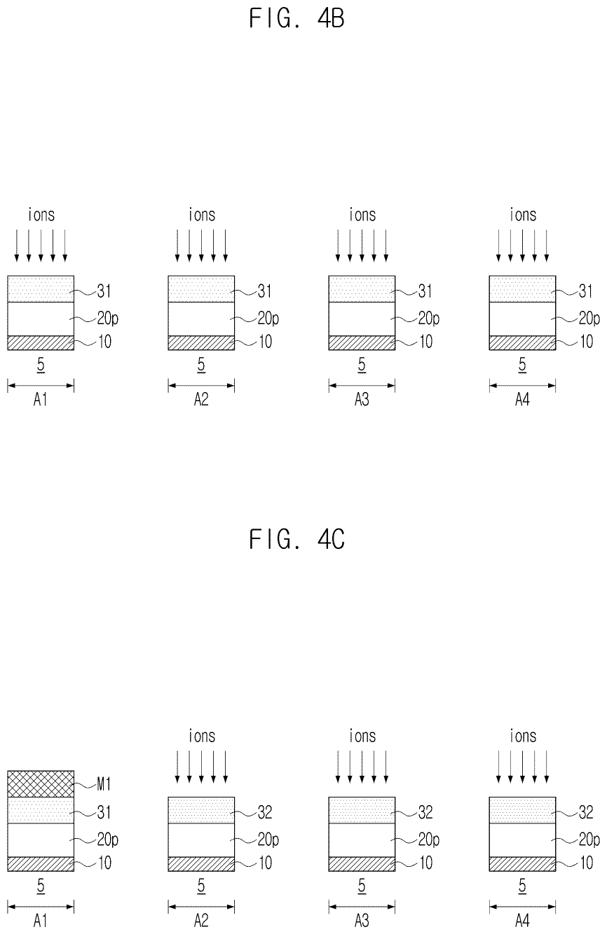

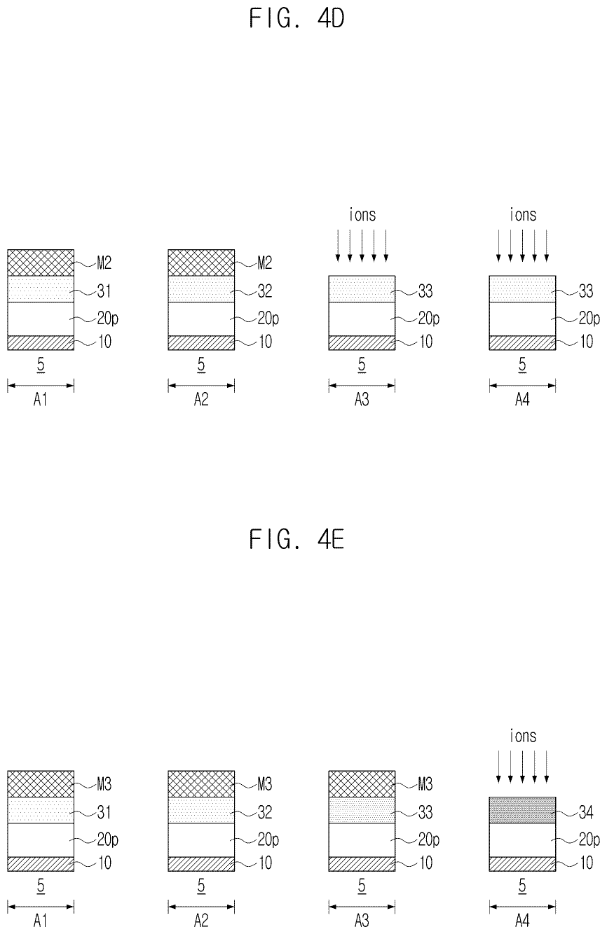

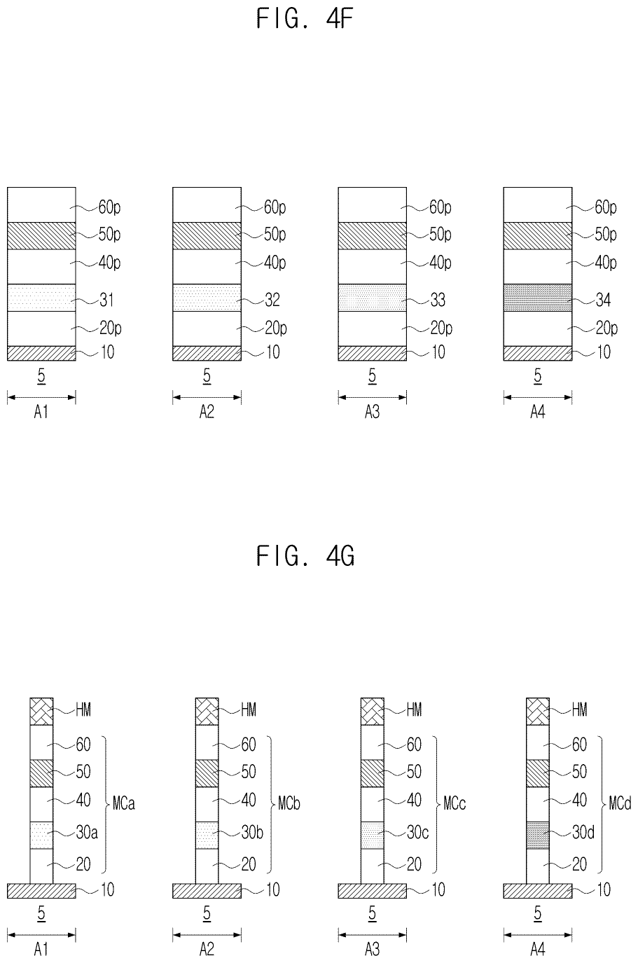

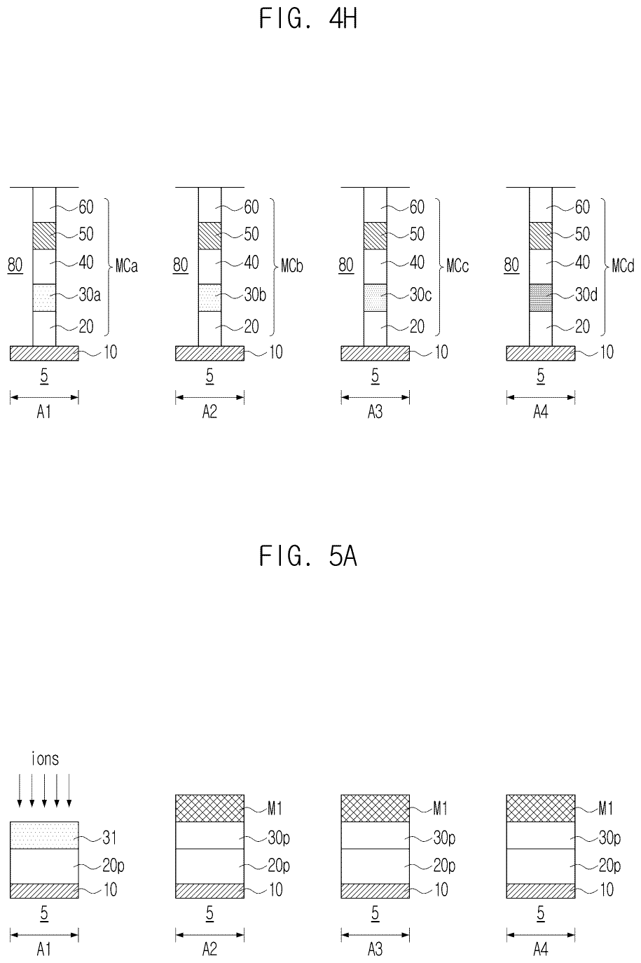

FIGS. 4A to 4H are cross-sectional views illustrating a method of forming memory cell structures 100a to 100d of a semiconductor device in accordance with an embodiment of the present disclosure. Referring to FIG. 4A, the method may include forming lower interconnection lines 10, a lower electrode material layer 20p, and a preliminary selection element material layer 30p, over a lower layer 5 having a first sub-cell area A1 to a fourth sub-cell area A4.

The lower layer 5 may include a single-layer or a multi-layer dielectric layer disposed over a silicon layer. For example, the lower layer 5 may include a silicon oxide layer or a silicon nitride layer.

Forming the lower interconnection lines 10 may include forming a plurality of interconnection lines extending in parallel to a horizontal direction by performing a deposition process, a photolithography process, and a patterning process. The lower interconnection lines 10 may include a metal, such as tungsten (W). In an embodiment of the present disclosure, the lower interconnection lines 10 may include a metal compound, such as titanium nitride (TiN).

Forming the lower electrode material layer 20p may include forming a metal compound, such as titanium nitride (TiN), by performing a deposition process onto the lower interconnection lines 10. In an embodiment of the present disclosure, the lower interconnection electrode material layer 20p may include a metal layer or a metal-silicide layer.

Forming the preliminary selection element material layer 30p may include forming a dielectric layer by performing a deposition process. The dielectric layer may include at least one of silicon oxide, silicon nitride, silicon oxynitride, a metal oxide, a metal nitride, and a metal oxynitride.

Referring to FIG. 4B, the method may further include performing a first doping process to dope the preliminary selection element material layer 30p with dopants. Accordingly, the preliminary selection element material layer 30p may be modified into the first selection element material layer 31 having a first dopant concentration. The dopants may include at least one of aluminum, lanthanum, niobium, vanadium, tantalum, tungsten, chromium, molybdenum, boron, nitrogen, carbon, phosphorus, and arsenic.

Referring to FIG. 4C, the method may further include forming a first doping mask pattern M1 that covers the first selection element material layer 31 of the first sub-cell area A1 and exposes the first selection element material layers 31 of the second to fourth sub-cell areas A2 to A4, and performing a second doping process to further dope the first selection element material layers 31 exposed in the second to fourth sub-cell areas A2 to A4 with dopants. The first selection element material layers 31 in the second to fourth sub-cell areas A2 to A4 may be modified into second selection element material layers 32. The dopants may include at least one of aluminum, lanthanum, niobium, vanadium, tantalum, tungsten, chromium, molybdenum, boron, nitrogen, carbon, phosphorus, and arsenic. The second selection element material layer 32 may have a second dopant concentration, and the second dopant concentration may be higher than the first dopant concentration. The first doping mask pattern M1 may include an organic pattern such as a photoresist or an inorganic dielectric pattern. The method may further include performing a first strip process to remove the first doping mask pattern M1.

Referring to FIG. 4D, the method may further include forming a second doping mask pattern M2 that covers the first selection element material layer 31 of the first sub-cell area A1 and the second selection element material layer 32 of the second sub-cell area A2 and exposes the second selection element material layers 32 of the third and fourth sub-cell areas A3 and A4, and performing a third doping process to further dope the second selection element material layers 32 exposed in the third and fourth sub-cell areas A3 and A4 with dopants. The second selection element material layers 32 in the third and fourth sub-cell areas A3 and A4 may be modified into third selection element material layers 33. The dopants may include at least one of aluminum, lanthanum, niobium, vanadium, tantalum, tungsten, chromium, molybdenum, boron, nitrogen, carbon, phosphorus, and arsenic. The third selection element material layer 33 may have a third dopant concentration, and the third dopant concentration may be higher than the second dopant concentration. The second doping mask pattern M2 may include the same material as that of the first doping mask pattern M1. The method may further include performing a second strip process to remove the second doping mask pattern M2.

Referring to FIG. 4E, the method may further include forming a third doping mask pattern M3 that covers the first selection element material layer 31 of the first sub-cell area A1, the second selection element material layer 32 of the second sub-cell area A2, and the third selection element material layer 33 of the third sub-cell area A3 and exposes the third selection element material layer 33 of the fourth sub-cell area A4, and performing a fourth doping process to further dope the third selection element material layer 33 exposed in the fourth sub-cell area A4 with dopants. The third selection element material layers 33 in the fourth sub-cell areas A4 may be modified into fourth selection element material layers 34. The dopants may include at least one of aluminum, lanthanum, niobium, vanadium, tantalum, tungsten, chromium, molybdenum, boron, nitrogen, carbon, phosphorus, and arsenic. Accordingly, the fourth selection element material layer 34 may have a fourth dopant concentration, and the fourth dopant concentration may be higher than the third dopant concentration. The third doping mask pattern M2 may include the same material as that of the first doping mask pattern M1 and/or the second doping mask pattern M2. The method may further include performing a third strip process to remove the third doping mask pattern M3.

Referring to FIG. 4F, the method may further include performing deposition processes onto the first to fourth selection element material layers 31 to 34 in the first to fourth sub-cell areas A1 to A4 to form an intermediate electrode material layer 40p, a memory element material layer 50p, and an upper electrode material layer 60p. Forming the intermediate electrode material layers 40p may include performing a deposition process to form a carbon layer. Forming the memory element material layer 50p may include performing a deposition process to form one of a transition metal oxide layer, a metal oxide layer such as a perovskite-based material, a phase change material layer such as a chalcogenide-based material, a ferroelectric material layer, and a ferromagnetic material layer. Forming the upper electrode material layer 60p may include performing a deposition process to form at least one of a metal layer such as tungsten (W), a metal compound layer such as titanium nitride (TiN), a metal alloy layer, and a metal silicide layer.

Referring to FIG. 4G, the method may further include forming hard mask patterns HM over the upper electrode material layer 60p in the first to fourth sub-cell areas A1 to A4 and performing a patterning process to form first to fourth memory cells MCa to MCd in the first to fourth sub-cell areas A1 to A4, respectively. A first memory cell MCa may be formed in the first sub-cell area A1, and a second memory cell MCb may be formed in the second sub-cell area A2, and a third memory cell MCc may be formed in the third sub-cell area A3, and a fourth memory cell MCd may be formed in the fourth sub-cell area A4. The first memory cell MCa may include a lower electrode 20, a first selection element layer 30a disposed over the lower electrode 20, an intermediate electrode 40 disposed over the first selection element layer 30a, a memory element layer 50 disposed over the intermediate electrode 40, and an upper electrode 60 disposed over the memory element layer 50. The second memory cell MCb may include a lower electrode 20, a second selection element layer 30b disposed over the lower electrode 20, an intermediate electrode 40 disposed over the second selection element layer 30b, a memory element layer 50 disposed over the intermediate electrode 40, and an upper electrode 60 disposed over the memory element layer 50. The third memory cell MCc may include a lower electrode 20, a third selection element layer 30c disposed over the lower electrode 20, an intermediate electrode 40 disposed over the third selection element layer 30c, a memory element layer 50 disposed over the intermediate electrode 40, and an upper electrode 60 disposed over the memory element layer 50. The fourth memory cell MCd may include a lower electrode 20, a fourth selection element layer 30d disposed over the lower electrode 20, an intermediate electrode 40 disposed over the fourth selection element layer 30d, a memory element layer 50 disposed over the intermediate electrode 40, and an upper electrode 60 disposed over the memory element layer 50. The first selection element layer 30a may include dopants of a first dopant concentration. The second selection element layer 30b may include dopants of a second dopant concentration. The third selection element layer 30c may include dopants of a third dopant concentration. The fourth selection element layer 30d may include dopants of a fourth dopant concentration. The hard mask pattern HM may include an organic layer such as a photoresist, an inorganic layer including silicon nitride or silicon oxide, or a metallic material layer including a metal or a metal compound.

Referring to FIG. 4H, the method may further include removing the hard mask pattern HM, forming an inter-layer dielectric layer 80, and performing a planarization process. Removing the hard mask pattern HM may include performing a strip process or a wet etching process. The hard mask pattern HM may be partially removed. For example, a portion of the hard mask pattern HM may remain over each of the upper electrodes 60 and may be included as a portion of each of the upper electrodes 60. The inter-layer dielectric layer 80 may include silicon oxide or silicon nitride that is formed by performing a deposition process. The planarization process may include a Chemical Mechanical Polishing (CMP) process. The upper surface of the inter-layer dielectric layer 80 and the upper surfaces of the upper electrodes 60 may be co-planar.

Subsequently, the method may further include forming upper interconnection lines 70 over the upper electrodes 60 of the first to fourth memory cells MCa to MCd by further referring to FIG. 3.

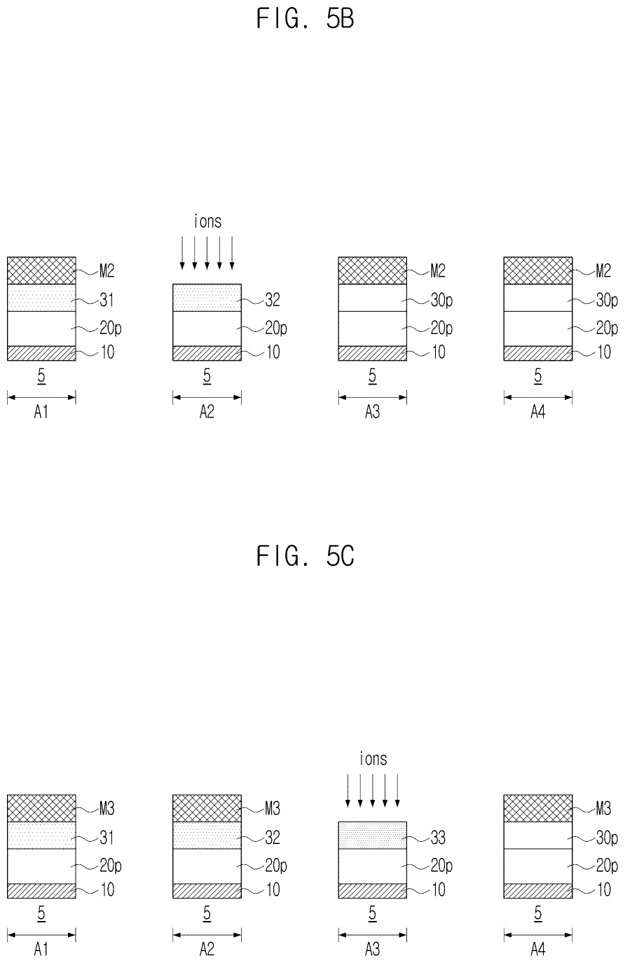

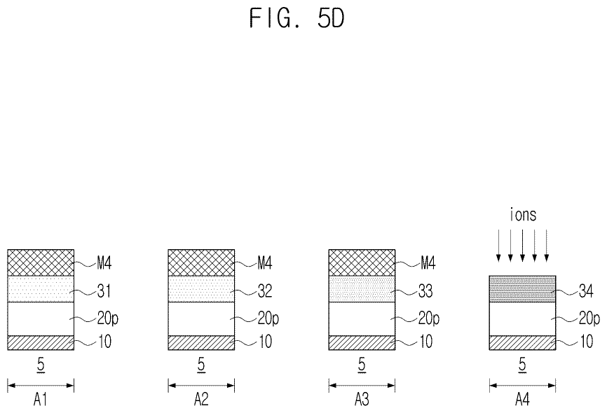

FIGS. 5A to 5D are cross-sectional views illustrating a method of forming memory cell structures 100a to 100d of a semiconductor device in accordance with an embodiment of the present disclosure.

Referring to FIG. 5A, the method of forming the memory cell structures 100a to 100d in accordance with the embodiment of the present disclosure may include performing the processes described earlier with reference to FIG. 4A, forming a first mask pattern M1 that exposes a preliminary selection element material layer 30p of a first sub-cell area A1 and covers the preliminary selection element material layers 30p of the second to fourth sub-cell areas A2 to A4, and performing a first doping process to implant dopants into the preliminary selection element material layer 30p exposed in the first sub-cell area A1. The preliminary selection element material layer 30p of the first sub-cell area A1 may be modified into a first selection element material layer 31. The method may further include removing the first mask pattern M1.

Referring to FIG. 5B, the method may further include forming a second mask pattern M2 that exposes the preliminary selection element material layer 30p of the second sub-cell area A2 and covers the first selection element material layer 31 of the first sub-cell area A1 and the preliminary selection element material layers 30p of the third and fourth sub-cell areas A3 and A4, and performing a second doping process to implant dopants into the preliminary selection element material layer 30p exposed in the second sub-cell area A2. The preliminary selection element material layer 30p of the second sub-cell area A2 may be modified into a second selection element material layer 32. The method may further include removing the second mask pattern M2.

Referring to FIG. 5C, the method may further include forming a third mask pattern M3 that covers the preliminary selection element material layer 30p of the third sub-cell area A3 and exposes the first selection element material layer 31 of the first sub-cell area A1, the second selection element material layer 32 of the second sub-cell area A2, and the preliminary selection element material layer 30p of the fourth sub-cell area A4, and performing a third doping process to implant dopants into the preliminary selection element material layer 30p exposed in the third sub-cell area A3. The preliminary selection element material layer 30p of the third sub-cell area A3 may be modified into a third selection element material layer 33. The method may further include removing the third mask pattern M3.

Referring to FIG. 5D, the method may include forming a fourth mask pattern M4 that exposes the preliminary selection element material layer 30p of the fourth sub-cell area A4 and covers the first to third selection element material layers 31 to 33 of the first to third sub-cell areas A1 to A3, and performing a fourth doping process to implant dopants into the preliminary selection element material layer 30p exposed in the fourth sub-cell area A4. The preliminary selection element material layer 30p of the fourth sub-cell area A4 may be modified into a fourth selection element material layer 34. The method may further include removing the fourth mask pattern M4.

Subsequently, the method may further include performing the processes described earlier by referring to FIGS. 4F to 4H, and forming upper interconnection lines 70 over the upper electrodes 60 of the first to fourth memory cells MCa to MCd by further referring to FIG. 3.

According to the embodiments of the present disclosure, the threshold voltage (Vth) of memory cells may be uniformized, regardless of their positions.

According to the embodiments of the present disclosure, the characteristics and operations of memory cells may be uniformized and stabilized.

While the present invention has been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A semiconductor device comprising:
a cell area including a first sub-cell area and a second sub-cell area;
a first peripheral circuit area adjacent to a first side of the cell area in a first direction; and
a second peripheral circuit area adjacent to a second side of the cell area in a second direction perpendicular to the first direction,
wherein:
the first sub-cell area includes a first memory cell disposed closer to the first and second peripheral circuit areas than the second memory cell;
the second sub-cell area includes a second memory cell disposed farther from the first and second peripheral circuit areas;
the first memory cell includes a first selection element layer and the second memory cell includes a second selection element layer, each of the first and second selection element layers including a dielectric material containing a dopant; and
a dopant concentration of the first selection element layer is lower than a dopant concentration of the second selection element layer.

2. The semiconductor device of claim 1, wherein each of the first selection element layer and the second selection element layer includes at least one of a silicon oxide, a silicon nitride, a silicon oxynitride, a metal oxide, a metal nitride, and a metal oxynitride.

3. The semiconductor device of claim 1, wherein the dopant includes at least one of aluminum, lanthanum, niobium, vanadium, tantalum, tungsten, chromium, molybdenum, boron, nitrogen, carbon, phosphorus, and arsenic.

4. The semiconductor device of claim 1, wherein:
the cell area further includes a third sub-cell area including a third memory cell disposed farther from the first peripheral circuit area than the second memory cell;
the third memory cell includes a third selection element layer including a dielectric material containing a dopant; and
a dopant concentration of the third selection element layer is higher than the dopant concentration of the second selection element layer.

5. The semiconductor device of claim 1, wherein:
the first memory cell includes a first lower electrode, the first selection element layer disposed over the first lower electrode, a first intermediate electrode disposed over the first selection element layer, a first memory element layer disposed over the first intermediate electrode, and a first upper electrode disposed over the first memory element layer; and
the second memory cell includes a second lower electrode, the second selection element layer disposed over the second lower electrode, a second intermediate electrode disposed over the second selection element layer, a second memory element layer disposed over the second intermediate electrode, and a second upper electrode disposed over the second memory element layer.

6. The semiconductor device of claim 5, wherein each of the first and second intermediate electrodes includes a carbon layer.

7. The semiconductor device of claim 5, wherein each of the first and second memory element layers includes a variable resistance element.

8. The semiconductor device of claim 5, wherein each of the first lower electrode, the first upper electrode, the second lower electrode, and the second lower electrode includes at least one of a metal and a metal compound.

9. The semiconductor device of claim 1, wherein a thickness of the first selection element layer and a thickness of the second selection element layer are identical.

10. The semiconductor device of claim 1, wherein:
the first selection element layer has a first threshold voltage; and
the second selection element layer has a second threshold voltage lower than the first threshold voltage.

11. A semiconductor device comprising:
a cell area including a first memory cell and a second memory cell; and
a first peripheral circuit area disposed adjacent to the cell area in a first direction,
wherein:
the first memory cell is disposed closer to the first peripheral circuit area than the second memory cell;
the first memory cell includes a first selection element layer having a first threshold voltage; and
the second memory cell includes a second selection element layer having a second threshold voltage lower than the first threshold voltage.

12. The semiconductor device of claim 11, wherein each of the first and third selection element layers includes a dielectric material containing a dopant, the dielectric material including one of a silicon oxide, a silicon nitride, a silicon oxynitride, a metal oxide, a metal nitride, and a metal oxynitride containing a dopant.

13. The semiconductor device of claim 12, wherein the dopant includes at least one of aluminum, lanthanum, niobium, vanadium, tantalum, tungsten, chromium, molybdenum, boron, nitrogen, carbon, phosphorus, and arsenic.

14. The semiconductor device of claim 11, further comprising a second peripheral circuit area disposed adjacent to the cell area in a second direction perpendicular to the first direction,
wherein the first memory cell is disposed closer to the second peripheral circuit area than the second memory cell.

15. The semiconductor device of claim 11, wherein:
the cell area further includes a third memory cell disposed farther from the first peripheral circuit area than the second memory cell; and
the third memory cell has a third threshold voltage lower than the second threshold voltage.

16. The semiconductor device of claim 11, wherein a thickness of the first selection element layer and a thickness of the second selection element layer are identical.

17. The semiconductor device of claim 11, wherein:
the first selection element layer includes a dielectric material containing a dopant of a first dopant concentration; and
the second selection element layer includes a dielectric material containing a dopant of a second dopant concentration higher than the first dopant concentration.

18. The semiconductor device of claim 11, wherein:
the first memory cell includes a first lower electrode, the first selection element layer disposed over the first lower electrode, a first intermediate electrode disposed over the first selection element layer, a first memory element layer disposed over the first intermediate electrode, and a first upper electrode disposed over the first memory element layer; and
the second memory cell includes a second lower electrode, the second selection element layer disposed over the second lower electrode, a second intermediate electrode disposed over the second selection element layer, a second memory element layer disposed over the second intermediate electrode, and a second upper electrode disposed over the second memory element layer.

19. The semiconductor device of claim 18, wherein:
each of the first and second intermediate electrodes includes a carbon layer; and
wherein each of the first and second memory element layers includes a variable resistance element.

20. The semiconductor device of claim 18, wherein each of the first lower electrode, the first upper electrode, the second lower electrode, and the second lower electrode includes at least one of a metal and a metal compound.
